(19) United States
(12) Patent Application Publication
(10) Pub. No.: US 2009/0206481 A1
(43) Pub. Date: Aug. 20, 2009

(54) STACKING OF TRANSFER CARRIERS WITH APERTURE ARRAYS AS INTERCONNECTION JOINTS

(75) Inventor: Cheng-Lien Chiang, Taipei (TW)

Correspondence Address: LOWE HAUPTMAN HAM & BERNER, LLP, 1700 DIAGONAL ROAD, SUITE 300, ALEXANDRIA, VA, 22314, US

(73) Assignee: NICHEPAC TECHNOLOGY INC., Taipei County (TW)

(21) Appl. No.: 12/430,216

(22) Filed: Apr. 27, 2009

Related U.S. Application Data
(63) Continuation-in-part of application No. 11/669,880, filed on Jan. 31, 2007.

(51) Int. Cl. H01L 23/498; H01L 21/768

(52) U.S. Cl. 257/738; 438/612; 257/762; 257/E23.069; 257/E21.585; 257/E23.06

(57) ABSTRACT

An interconnection mechanism between plated through holes is disclosed, a first embodiment includes a first substrate having a first plated through hole; a second substrate having a second plated through hole; a metal core is configured in between the two plated through holes; the metal ball has a diameter larger than a diameter of the plated through holes; and melted solder binds the first plated through hole, metal core, and the second plated through hole. A second embodiment includes stacked substrate having a gold plated only on ring pads of the plated through holes; melted solder binds the two gold ring pads.

This application is a continuation-in-part application of U.S. application Ser. No. 11/669,880 filed on Jan. 31, 2007, the disclosure of which is incorporated by reference herein in its entirety.

### BACKGROUND

1. Field of Invention

The present invention relates to a stacking of transfer carriers. More particularly, the present invention relates to a stacking of transfer carriers with aperture arrays as interconnection joints.

2. Description of Related Art

Various techniques of chip stacking have developed over the years to stack integrated circuit packages in a compact and low profile manner. In stacking fine-pitch ball grid array (FBGA) packages, a transfer substrate acting as a supporting plate and provides interconnection between the FBGA packages is used to transfer the electrical signal. The integrated circuit package is electrically connected to the conductive patterns of the transfer substrate arranged in the same pattern as the package pin configuration via solder balls. The transfer substrate also has pad arrays disposed near the edges of the substrate to make connection with other transfer substrates. The conductive patterns and pad arrays are metal layers formed on both sides of the transfer substrate and are connected with their counter part on the opposite side by metal via.

The manufacturing of transfer substrates with pads as interconnection joints adds complexity to the interconnect substrate with additional metal via needed to connect corresponding pads on both sides of the substrate. Also, with the pads as interconnection joints, these are no variations of how the interconnection joints can be connected. The pads may only be soldered together via solder balls. Therefore a new interconnection joint structure is needed to simplify the manufacturing process and also provides variation in joining the interconnection joints.

### SUMMARY

The present invention is directed to a transfer carrier that it satisfy this need of a new interconnection joint. The transfer carrier comprises a transfer substrate, two aperture arrays, a conductive pattern, and a semiconductor device. The semiconductor device may be an integrated circuit package or a bare die. When the semiconductor device is an integrated circuit package, such as a FBGA packaged memory chip, it is connected to the transfer substrate by making a solder connection with the conductive pattern. The conductive pattern may be apertures with conductive plating around the rim of the apertures on the bottom surface of the transfer substrate. Solder paste may be applied filling the apertures. The conductive plating is on each aperture of the conductive pattern is electrically connected to the corresponding apertures of the two aperture arrays. The two aperture arrays located on the opposite sides of the transfer substrate defining a cavity, the aperture arrays have conductive layers, such as conductive plating, on the inner side of the apertures extending from the top surface to the bottom surface of the substrate. The semiconductor device is placed in the cavity so that the thickness of the device does not exceed the height of the sidewall of the cavity. The conductive plating may further extend onto the top and bottom surface of the substrate around the rim of the apertures. The conductive layers provide electric conduction from the top surface to the bottom surface of the transfer substrate. By using apertures as interconnection joints, it eliminated the need for disposing top and bottom surface pads and the connecting metal via. The connection between the top and bottom surface in the present invention is through a simple puncture and a single plating process. The transfer carriers may be stacked by planting conductive contacts in the aperture or making connections around the rims of the aperture providing a hollow connection joint.

When the semiconductor device is a bare die, the conductive pattern may be pads disposed on the bottom surface of the transfer substrate making a bond wire connection with the bond pads on the bare die. An epoxy layer fills the cavity encapsulating the bare die to complete the package.

The aperture interconnection joint structure may also be applied to the molding of a new integrated circuit package. Instead of using a transfer carrier, the aperture arrays are formed as leads of a lead frame package of a bare die. The lead frame package is encapsulated by a molding compound with pads disposed thereon and exposing the leads.

The integrated circuit package may be stacked in the same manner as the transfer carrier while each integrated circuit package is smaller in size than the transfer carrier.

The present invention provides a transfer carrier with aperture arrays as interconnection joints. Using apertures as interconnection joints simplifies the transfer substrate manufacturing process and also provides variation in joining the interconnection joints.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a top, bottom and side view of the transfer carrier according to the first embodiment of the present invention;

FIG. 2A is a cross section view of one plating option according to the first embodiment of the present invention;

FIG. 2B is a cross section view of one plating option according to the first embodiment of the present invention;

FIG. 2C is a cross section view of one plating option according to the first embodiment of the present invention;

FIG. 2D is a cross section view of one plating option according to the first embodiment of the present invention;

FIG. 3A is a diagram of the second embodiment of the present invention;

FIG. 3B is a bottom view according to the second embodiment of the present invention;

FIG. 3C is a top view according to the second embodiment of the present invention;

FIG. 4 is a side view of the stacking module;

FIG. 5A is a cross section view of one interconnection option of the interconnection joint;

FIG. 5B is a cross section view of one interconnection option of the interconnection joint;

FIG. 5C is a cross section view of one interconnection option of the interconnection joint;

FIG. 6A is a diagram of the integrated circuit package according to the third embodiment of the present invention;

FIG. 6B is a transparent side view of the integrated circuit package according to the third embodiment of the present invention;

FIG. 6C is a diagram of the integrated circuit package according to the third embodiment of the present invention;

FIG. 7A is a cross section view of one stacking option of the integrated circuit packages;

FIG. 7B is a cross section view of one stacking option of the integrated circuit packages; and

FIG. 7C is a cross section view of one stacking option of the integrated circuit packages.

FIG. 8A shows a first interconnection embodiment of this invention with a solder coated metal ball configured in between two plated through holes.

FIG. 8B shows an enlarged view of metal layers of the plated through holes and ring pads of the carrier of FIG. 8A.

FIG. 8C shows melted solder binding and electrically coupling the two plated through holes after heating the combination of FIG. 8A.

FIG. 9A shows a second interconnection embodiment of this invention with gold/solder ring pads.

FIG. 9B shows an enlarged view of metal layers of the wall in the plated through holes and ring pads on the surface of the carrier of FIG. 9A.

FIG. 9C shows melted solder binding the combination of FIG. 9A

FIG. 10A shows a third interconnection embodiment of this invention with gold/solder ring pads.

FIG. 10B shows an enlarged view of metal layers of the wall in the plated through holes and ring pads on the surface of the carrier of FIG. 10A.

FIG. 10C shows melted solder binding the combination of FIG. 10A

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

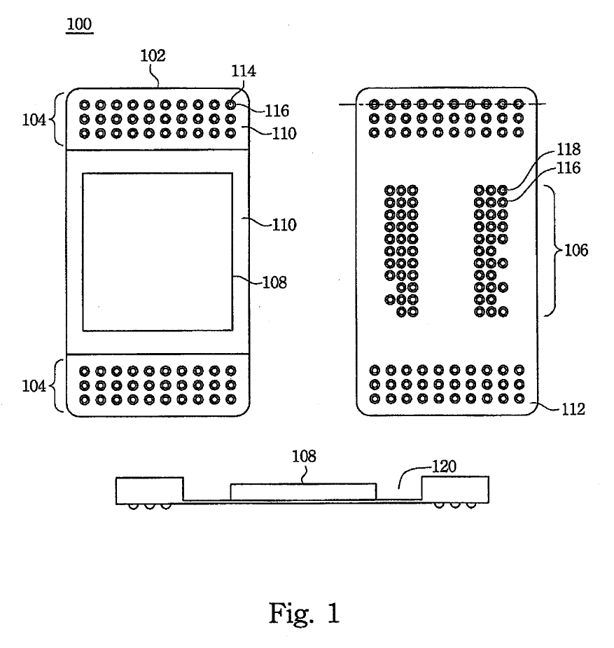

Please refer to FIG. 1, a top, bottom and side view of the transfer carrier according to the first embodiment of the present invention. The transfer carrier 100 includes a transfer substrate 102, two aperture arrays 104, a conductive pattern 106, and a semiconductor device 108. The transfer substrate defines a top surface 110 and a bottom surface 112. The two aperture arrays 104 have apertures 114 extending from the top surface 110 through to the bottom surface 112. The two aperture arrays 104 are located on the opposite sides of the transfer substrate 102 and defining a cavity 120. The cavity 120 allows the thickness of semiconductor device 108 to be not higher than the depths of the cavity 120, creating a stackable structure. The apertures 114 have conductive plating 116 formed in the aperture. The conductive plating 116 is a plated through hole (PTH) plating using a metal such as gold, silver, tin, tin-lead alloy, copper alloy, aluminum, or the combination thereof. The contact pattern 106 is located between the two aperture arrays 104. The contact pattern 106 is composed of contacts 118 extending from the top surface 110 through to the bottom surface 112, the contacts 118 are electrically connected to the corresponding conductive plating 116 of the apertures 114. The contacts 118 are apertures having conductive plating 116 around the rim of the apertures on the bottom surface 112. Finally, the semiconductor device 108, which has pads (not shown) arranged in identical pattern as the contact pattern 106, is electrically connected to the contacts 118. Therefore, by accessing the conductive plating on the two aperture arrays 104, one has access to the semiconductor device.

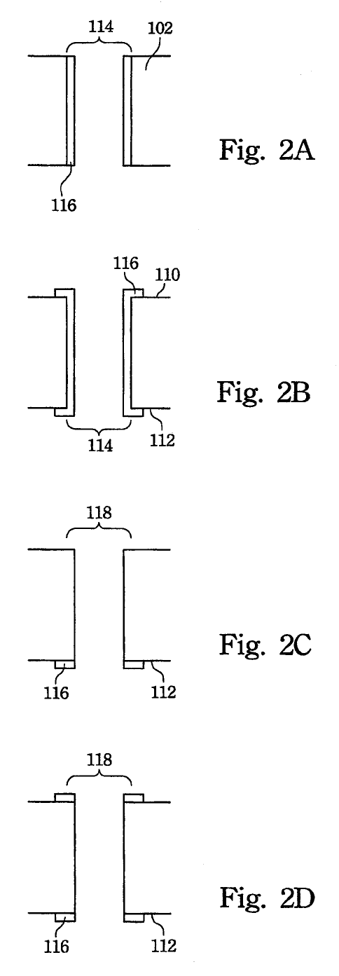

Referring to FIGS. 2A, 2B, 2C, and 2D simultaneously, cross section views of plating options along the line AB of an aperture in FIG. 1. In FIG. 2A, the conductive plating 116 covers the inner surface of the apertures 114. In FIG. 2B, the conductive plating 116 extends onto the top surface 110 and bottom surface 112. In FIG. 2C, the cross section view of a contact 118, the conductive plating 116 is formed on the bottom surface 112 around the rim of the contact 118. In FIG. 2D, the conductive plating 116 is formed on the top surface 110 and the bottom surface 112 around the rim of the contact 118.

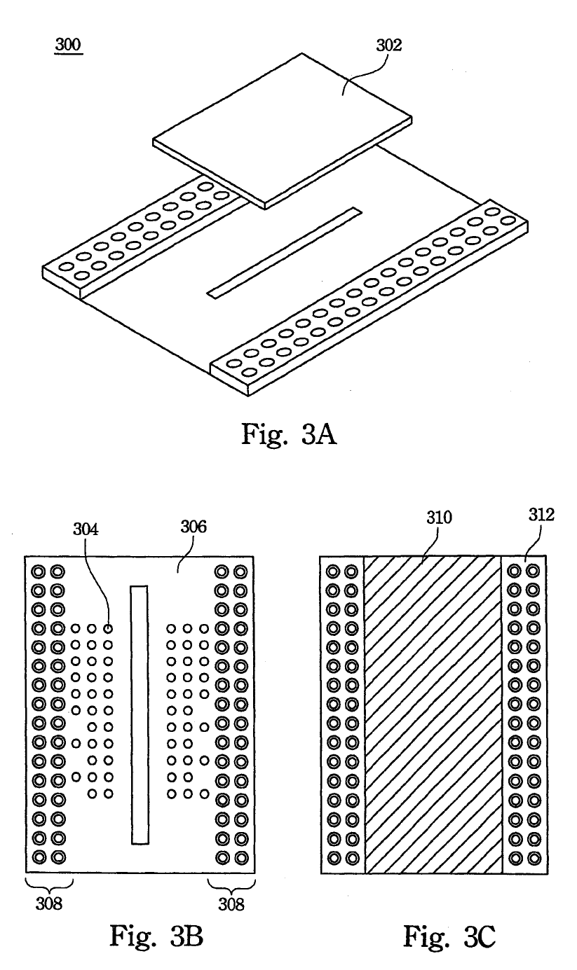

Please refer to FIGS. 3A, 3B and 3C simultaneously, diagrams of the second embodiment of the present invention. In FIG. 3A, the transfer carrier 300 has the same structure as the transfer carrier 100, except that the semiconductor device is an unpackaged bare die 302. The bare die 302 may be a DRAM die, a NOR flash die, a NAND flash die, or a MRAM die. The bare die 302 has bond pads (not shown) electrically connected through bond wires (not shown) with the contacts 304 on the bottom surface 306 shown in FIG. 3B. The contacts 304 are conductive pads with flat metal surfaces. The contacts 304 are electrically connected to the two aperture arrays 308 to provide stackable access to the bare die 302. In FIG. 3C, an epoxy layer 310 is applied filling the cavity on the top surface 312 to provide protection for the bare die 302.

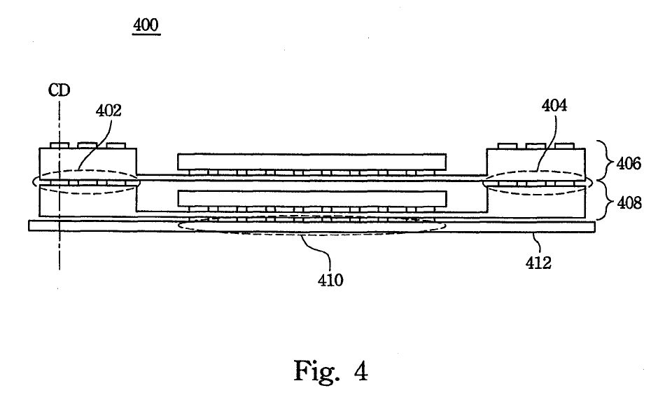

Please refer to FIG. 4, a side view of the stacked module 400 of the transfer carriers 100 described above. A conductive contact is applied at the interconnection joints 402 and 404 to secure connection between the transfer carrier 406 and transfer carrier 408. The conductive contacts are also applied to the interconnection joints 410 to secure connection between the transfer carriers 406, 408 and the printed circuit board 412. The conductive contact may be an electrically conductive adhesive contact, a mechanically structured contact, or a combined application of the electrically conductive adhesive contact and the mechanically structured contact.

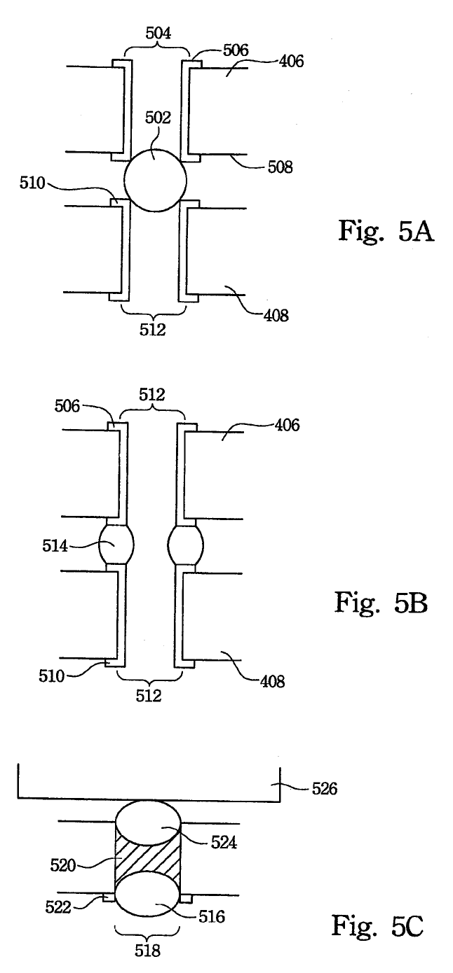

Please refer to FIGS. 5A, 5B, and 5C simultaneously, cross section diagrams of interconnection options applied to the interconnection joints 402, 404, and 410 along the line CD. In FIG. 5A, a conductive contact 502 is planted into the aperture 504 making contact with the conductive plating 506 and protruding out of the bottom surface 508 of the transfer carrier 406. The conductive contact 502 is then connected with the corresponding conductive plating 510 of the aperture 512 on the transfer carrier 408. In FIG. 5B, a conductive contact 514 is applied on around the rim of the aperture 504 making contact with the conductive plating 506. The conductive contact 514 is then soldered onto the corresponding conductive plating 510 of the aperture 512 on the transfer carrier 408. In FIG. 5C, the interconnection option of interconnection joint 410, a conductive contact 516 is planted into the aperture 518 and solder paste 520 fills the apertures 518 providing electrical conduction between the conductive contact 516 and the conductive plating 522. The solder ball 524 on the pads of the semiconductor device 526 is inserted into the aperture 518 making electrical connection with the conductive plating 522 and the conductive contact 516. The conductive contact 502, 514, and 516 may be a solder ball, a solder plated copper ball, a solder plated epoxy ball, a solder plated rubber ball, a solder plated rosin ball, a metal ball or an alloy ball. The transfer carrier 300 in FIGS. 3a, 3b, and 3c may be stacked the same way as described above, and therefore no additional explanation is provided here.

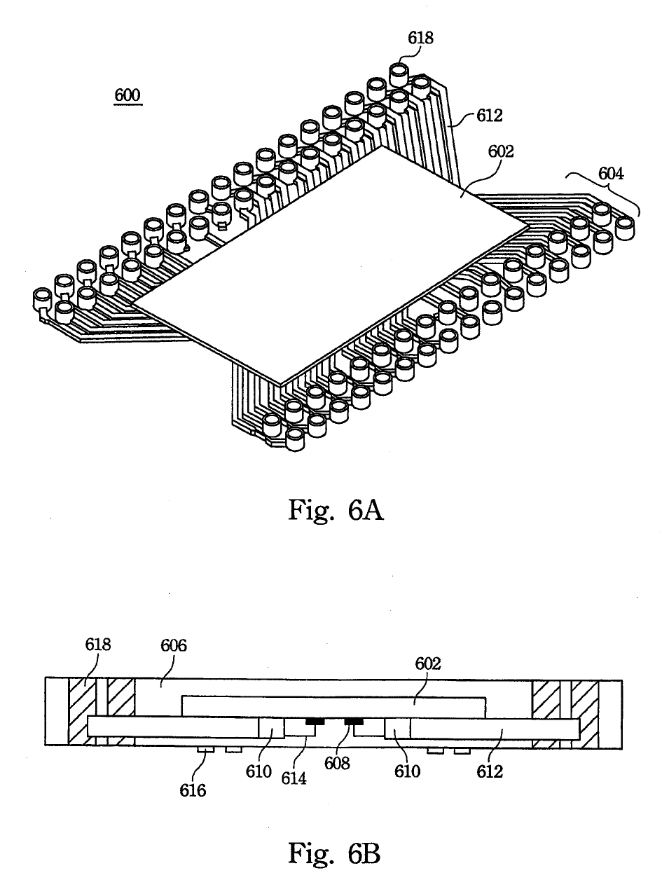

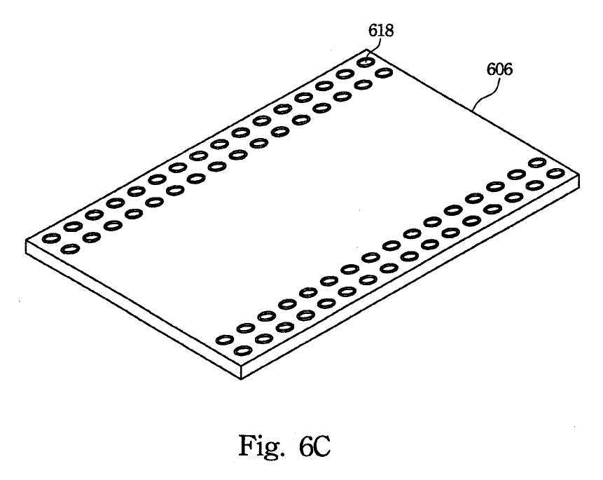

Please refer to FIGS. 6A, 6B, and 6C simultaneously, diagrams of the third embodiment according to the present invention. In this embodiment, FIG. 6A shows the integrated circuit package 600 includes a semiconductor die 602 and a leadframe 604. In FIG. 6B, a transparent side view of the third embodiment, the semiconductor die 602, such as a DRAM die, a NOR flash die, a NAND flash die, or a MRAM die having bond pads 608 electrically connected to a first end 610 of the lead fingers 612 via bond wires 614. The bond wires (not shown) also connect the bond pads 608 to the conductive pads 616 disposed on the molding compound 606. The second end of the lead fingers 612 extends and makes electrical connection with the outer surface of the leads 618 of the lead frame 604. The leads 618 are formed in a hollow cylindrical shape arranged in two arrays providing access to the bond pads 608. In FIG. 6C, the molding compound 606, such as epoxy, encapsulates the semiconductor die 602, the bond wires 614, the lead fingers 612 and the outer surface of the leads 618 completing the integrated circuit package 600. The leads 618 are kept hollow at the center, forming apertures similar to the apertures of the first and second embodiments. The lead frame 604 is made of a copper based alloy material or an alloy-42 material.

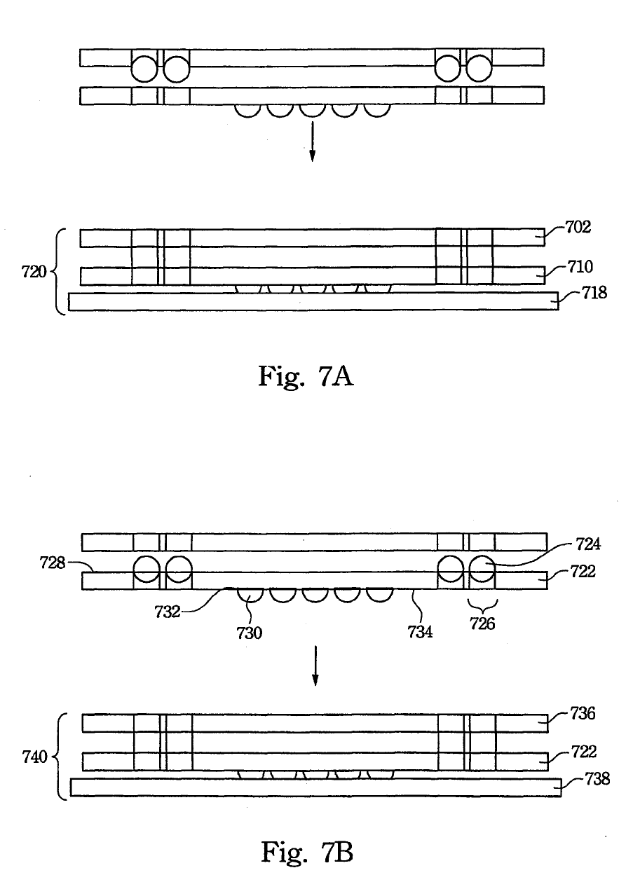

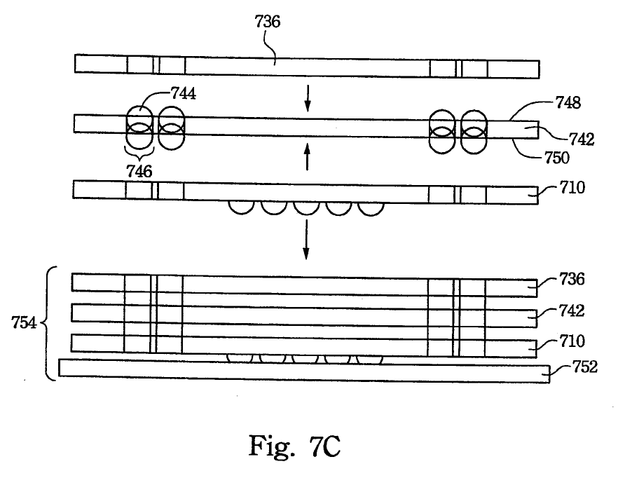

Please refer to FIGS. 7A, 7B, and 7C, diagrams of stacking options of the integrated circuit packages 600. In FIG. 7A, integrated circuit package 702 has solder balls 704 planted into the aperture 706, protruding out of the bottom surface 708. The integrated circuit package 710 has solder balls 712 attached to the conductive pads 714 and protruding out of the bottom surface 716. The integrated circuit packages 702 and 710 may be stacked onto a printed circuit board 718 to form a stacking module 720. In FIG. 7B, integrated circuit package 722 has solder balls 724 planted into the aperture 726 and protruding out of the top surface 728. The integrated circuit package 722 also has solder balls 730 attached to the conductive pads 732 and protruding out of the bottom surface 734. The integrated circuit package 722 and 736 are stacked onto a printed circuit board 738 to form a stacking module 740. Lastly, in FIG. 7C, integrated circuit 742 has solder balls 744 planted into the aperture 746 and protruding out of the top surface 748 and bottom surface 750. The integrated circuit packages 736, 742 and 710 are stacked onto a printed circuit board 752 to form a stacking module 754.

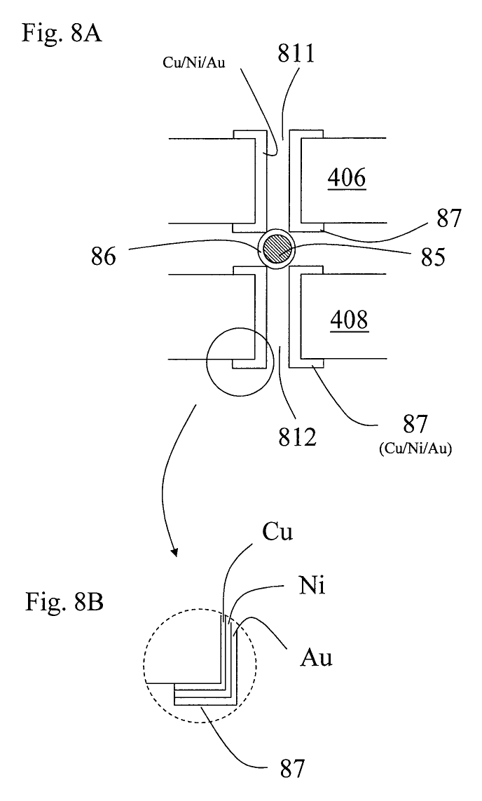

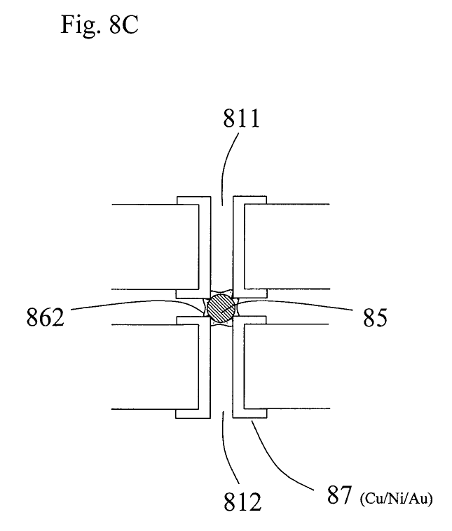

FIG. 8A shows a first interconnection embodiment of this invention with a solder coated metal ball configured in between two plated through holes.

A first transfer carrier 406 has a first plated through hole (PTH) 811, a second transfer carrier 408 has a second plated through hole 812. A solder coated metal ball (85+86) is configured in between the two plated through holes 811, 812 as shown in FIG. 8A. The metal layers of the plated through hole 811, 812 is Cu/Ni/Au, in other words, Nickel (Ni) is coated over Copper (Cu) and then Gold (Au) is coated over Nickel (Ni). Each of the plated through holes 811, 812 has a ring pad 87 of copper/nickel/gold (Cu/Ni/Au). A metal ball 85 coated with solder 86 is configured in between the first plated through hole 811 and the second plated through hole 812. The metal ball 85 has a diameter larger than a diameter of both the first plated through hole 811 and the second plated through hole 812, after heating to melt the solder 86, the metal ball 85 shall be inlaid in between the two plated through holes 811 and 812. The metal ball 85 has a melting point higher than the melting point of solder 86 so that the metal ball 85 may keep its original profile after heating to melt the solder 86. The metal ball can be one of Au, Ag, Al . . . etc. each of which has a melting point higher then solder (SnPb).

FIG. 8B shows an enlarged view of metal layers of the plated through holes and ring pads of the carrier of FIG. 8A.

The metal layers for the through hole 811, 812 and the ring pads 87 are the same, typically they are Cu/Ni/Au, i.e. nickel (Ni) is plated over Copper (Cu), and then gold (Au) is plated over copper (Cu).

FIG. 8C shows melted solder binding and electrically coupling the two plated through holes after heating the combination of FIG. 8A.

Melted solder 862 binding and electrically coupling the two plated through holes 811, 812 after heating the combination of FIG. 8A is shown in FIG. 8C. After heating the combination of FIG. 8A, solder 86 becomes melted solder 862 and binds the first plated through hole 811, the metal ball 85, and the second plated through hole 812 together, and meanwhile the two plated through holes 811, 812 are electrically coupled.

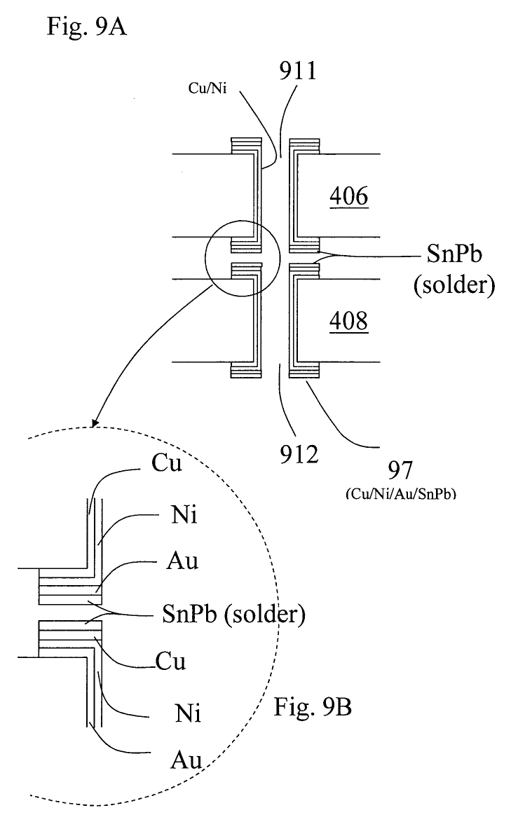

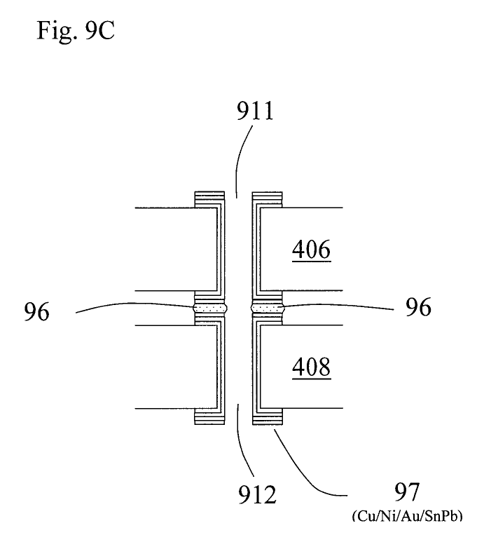

FIG. 9A shows a second interconnection embodiment of this invention with gold/solder ring pads.

A first transfer carrier 406 has a first plated through hole (PTH) 911, a second transfer carrier 408 has a second plated through hole 912. Each of the plated through holes 911, 912 has a through hole plated with Cu/Ni, and a ring pad 97 plated with Cu/Ni/Au/Sn—Pb on the top surface and bottom surface of the carrier 406 and 408. Each of the gold/solder ring pads is surrounding and electrically connecting with the metal layers on the wall of a corresponding plated through holes 911, 912. The metal layers for the wall of the holes are Cu/Ni and the metal layers for the ring pads on the surfaces are Cu/Ni/Au/solder. Gold (Au) is coated only on the ring pads but not coated on the wall of the plated through holes 911, 912. In other words, Nickel (Ni) is plated as a surface metal on the wall of the plated through holes 911, 912, which has a surface tension repelling wetting effect to melted solder. Gold/solder (Au/SnPb) are plated on the ring pads over nickel (Ni), and gold has a surface tension displaying wetting effect to melted solder.

FIG. 9B shows an enlarged view of metal layers of the wall in the plated through holes and ring pads on the surface of the carrier of FIG. 9A.

The metal layers on the wall of the holes 911, 912 are Cu/Ni, i.e. Nickel is coated over Copper (Cu). The metal layers of the ring pads 97 are Cu/Ni/Au/SnPb, i.e. Nickel is coated over Copper (Cu), gold (Au) is coated over Nickel (Ni), and then solder (Sn—Pb) is coated over gold (Au). The metal layers of the plated through holes 911, 912 and ring pads 97 are different in this embodiment. The gold-solder (Au—SnPb) are coated only on the ring pads but not coated on the wall of the through holes 911, 912.

FIG. 9C shows melted solder binding the combination of FIG. 9A.

The combination of FIG. 9A is then heated to melt the solder (SnPb) to bind and electrically couple plated through holes 911, 912 of the first carrier 406 and the second carrier 408. Melted solder 96 coagulates only in between the gold (Au) ring pads 97. Melted solder 96 shall not enter the through holes 911, 912 because of the surface tension difference in between Nickel (Ni) and Gold (Au) pads as shown in FIG. 9C. The gold (Au) has a surface tension displaying wetting effect to solder (SnPb) and nickel (Ni) has a surface tension repelling wetting effect to solder (SnPb).

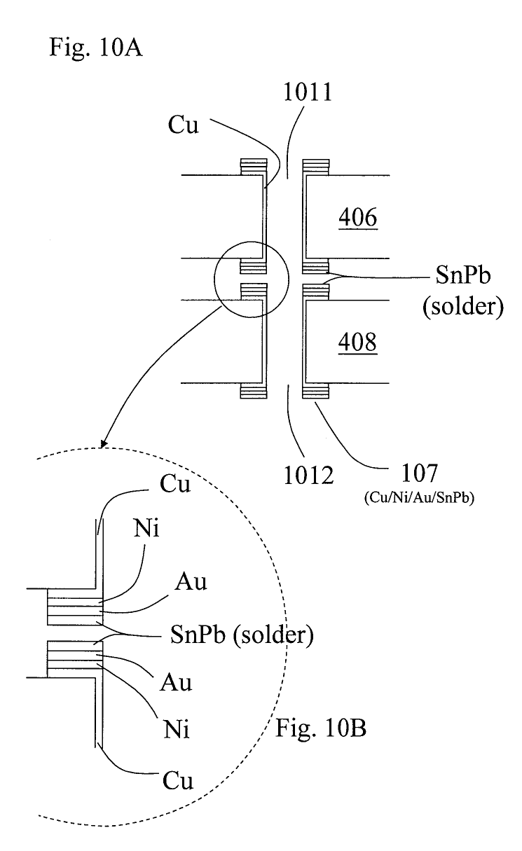

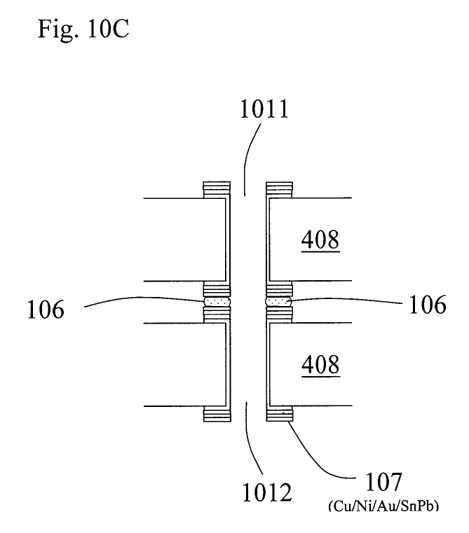

FIGS. 10A, 10B and 10C is similar to that has been described for FIGS. 9A, 9B, and 9C only that the metal layers difference on the wall in the plated through hole. FIGS. 10A, 10B and 10C has only copper (Cu) plated on the wall of the plated through hole. The remaining principle is the same as that has been described for FIG. 9A-9C.

FIG. 10A shows a third interconnection embodiment of this invention with gold/solder ring pads.

A first transfer carrier 406 has a first plated through hole (PTH) 1011, a second transfer carrier 408 has a second plated through hole 1012. Each of the plated through holes 1011, 1012 has a through hole plated with Cu, and a ring pad 107 made of Cu/Ni/Au/Sn—Pb on the top surface and bottom surface of the carrier 406 and 408. Each of the gold/solder ring pads 107 is surrounding and electrically connecting with the metal layers on the wall of a corresponding plated through holes 1011, 1012. The metal layers for the wall of the holes are Cu and the metal layers for the ring pads on the surfaces are Cu/Ni/Au/solder. Nickel/Gold (Ni/Au) are coated only on the ring pads but not coated on the wall of the plated through holes 1011, 1012. In other words, Copper (Cu) is plated as a surface metal on the wall of the plated through holes 1011, 1012, which has a surface tension repelling wetting effect to melted solder. Gold/solder (Au/SnPb) are plated on the ring pads over nickel (Ni), and gold has a surface tension displaying wetting effect to melted solder.

FIG. 10B shows an enlarged view of metal layers of the wall in the plated through holes and ring pads on the surface of the carrier of FIG. 10A.

The metal layers on the wall of the holes 1011, 1012 are Cu. The metal layers of the ring pads 107 are Cu/Ni/Au/SnPb, i.e. Nickel is coated over Copper (Cu), gold (Au) is coated over Nickel (Ni), and then solder (Sn—Pb) is coated over gold (Au).

FIG. 10C shows melted solder binding the combination of FIG. 10A.

The combination of FIG. 10A is then heated to melt the solder (SnPb) to bind and electrically couple plated through holes 1011, 1012 of the first carrier 406 and the second carrier 408. Melted solder 106 coagulates only in between the gold (Au) ring pads 107. Melted solder 106 shall not enter the through holes 1011, 1012 because of the surface tension difference in between Copper (Cu) and Gold (Au) pads as shown in FIG. 10C. The gold (Au) has a surface tension displaying wetting effect to solder (SnPb) but copper (Cu) has a surface tension repelling wetting effect to solder (SnPb).

The embodiments according to the present invention provide a transfer carrier with apertures as interconnection joints. The transfer carrier may be packaged chips attached to a transfer substrate, a bare die attached to a transfer substrate, or a semiconductor die molded as a transfer carrier. The aperture interconnection joints are easier to manufacture than conductive pads and provides a more solid conductive path from the top surface of the transfer carrier to the bottom surface of the transfer carrier. Also, the aperture allows variation in soldering together the interconnection joints as described in the above soldering options. The variation will be advantageous in future stacking applications of transfer carriers.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An interconnection mechanism between plated through holes, comprising:
a first substrate, having a first plated through hole;
a second substrate, having a second plated through hole;
a metal core, being configured in between said first plated through hole and said second plated through hole; said metal ball having a diameter larger than a diameter of both said first plated through hole and said second plated through hole; and
melted solder, binding said first plated through hole, said metal core, and said second plated through hole together.

2. An interconnection mechanism between plated through holes as claimed in claim 1, wherein said metal core is a metal ball.

3. An interconnection mechanism between plated through holes as claimed in claim 1, wherein said metal core has a melting point higher than that of a solder.

4. An interconnection mechanism between plated through holes as claimed in claim 1, wherein said metal core is selected from a group consisted of Au, Ag, and Al.

5. A method for preparing an interconnection between plated through holes, comprising:
preparing a first substrate having a first plated through hole;
preparing a second substrate having a second plated through hole;
preparing a solder coated metal core; wherein said core having a diameter larger than a diameter of said first plated through hole and said second plated through hole;
configuring said solder coated metal core in between said first plated through hole and said second plated through hole; and
heating to melt said solder for binding said first plated through hole, metal core, and said second plated through hole together.

6. An interconnection mechanism between plated through holes as claimed in claim 5, wherein said metal core is a metal ball.

7. An interconnection mechanism between plated through holes as claimed in claim 6, wherein said metal core has a melting point higher than that of a solder.

8. An interconnection mechanism between plated through holes, comprising:
stacked substrates, each having a plated through hole and a ring pad; wherein said plated through hole having a first surface metal having a surface tension repelling wetting effect to melted solder on a wall surface of the hole; and said ring pad having a second surface metal with a surface tension displaying wetting effect to melted solder; and
melted solder, coagulated over said second surface metal of said ring pads to bind said ring pads in between said first substrate and said second substrate.

9. An interconnection mechanism between plated through holes as claimed in claim 8, wherein said first surface metal is nickel (Ni) or copper (Cu).

10. An interconnection mechanism between plated through holes as claimed in claim 8, wherein said second surface metal is gold (Au).

11. A method for preparing an interconnection between plated through holes, comprising:
preparing a first and a second substrates, each having a plated through hole and a ring pad;
wherein said plated through hole further comprises a first surface metal having a surface tension repelling wetting effect to solder on a wall surface of the hole; and a second surface metal with a surface tension displaying wetting effect to solder; stacking said first substrate and said second substrates; and
heating to melt the solder so that the solder being coagulated over said second surface metal on said ring pads to bind said ring pads in between said first substrate and said second substrate.

12. An interconnection mechanism between plated through holes as claimed in claim 11, wherein said first surface metal is nickel (Ni) or copper (Cu).

13. An interconnection mechanism between plated through holes as claimed in claim 11, wherein said second surface metal is gold (Au).
